(19) United States
(12) Patent Application Publication
(10) Pub. No.: US 2024/0162681 A1
(43) Pub. Date: May 16, 2024

(54) OPTOELECTRONIC SEMICONDUCTOR CHIP

(71) Applicant: ams-OSRAM International GmbH, Regensburg (DE)

(72) Inventors: Hubert HALBRITTER, Dietfurt (DE); Bruno JENTZSCH, Regensburg (DE); Alvaro GOMEZ-IGLESIAS, Regensburg (DE)

(73) Assignee: ams-OSRAM International GmbH, Regensburg (DE)

(21) Appl. No.: 18/552,795

(22) PCT Filed: Mar. 2, 2022
(86) PCT No.: PCT/EP2022/055266

§ 371 Date: Sep. 27, 2023

(30) Foreign Application Priority Data
Mar. 31, 2021 (DE) 102021108200.5

(51) Int. Cl. H01S 5/042; H01S 5/026; H01S 5/028; H01S 5/10; H01S 5/187; H01S 5/343

(52) U.S. Cl. CPC H01S 5/04256; H01S 5/026; H01S 5/028; H01S 5/1085; H01S 5/187; H01S 5/34333

(57) ABSTRACT

In at least one embodiment, the optoelectronic semiconductor chip including a semiconductor layer sequence, in which there is at least one active zone for generating radiation; and a first electrode and a second electrode, with which the semiconductor layer sequence is in electrical contact; wherein the semiconductor layer sequence has, in the region of the active zone, at least one obliquely extending facet designed for a beam deflection of the radiation; wherein the first electrode and the second electrode are on the same mounting side of the semiconductor layer sequence as the at least one obliquely extending facet, and the mounting side is a main side of the semiconductor layer sequence; and wherein the radiation is coupled out on an emission side of the semiconductor layer sequence opposite from the mounting side.

### CROSS-REFERENCE TO RELATED APPLICATIONS

The present application is a national stage entry from International Application No. PCT/EP2022/055266, filed on Mar. 2, 2022, published as International Publication No. WO 2022/207221 A1 on Oct. 6, 2022, and claims priority to German Patent Application No. 10 2021 108 200.5, filed Mar. 31, 2021, the disclosures of all of which are hereby incorporated by reference in their entireties.

### FIELD OF THE INVENTION

An optoelectronic semiconductor chip is provided.

### BACKGROUND OF THE INVENTION

In documents US 2009/0097519 A1 and WO 2019/170636 A1, semiconductor lasers with oblique oriented deflection facets can be found.

A problem to be solved is to provide an optoelectronic semiconductor chip that can be manufactured efficiently.

This object is solved, inter alia, by an optoelectronic semiconductor chip having the features of the independent patent claim. Preferred further embodiments are the subject of the dependent claims.

### SUMMARY OF THE INVENTION

According to at least one embodiment, the optoelectronic semiconductor chip comprises a semiconductor layer sequence in which one or more active zones for generating radiation are located. The at least one active zone contains in particular at least one pn junction and/or at least one quantum well structure. The term ‘quantum well’ does not unfold any meaning with respect to a dimensionality of the quantization. The term ‘quantum well’ thus includes, for example, multidimensional quantum wells, one-dimensional quantum wires and quantum dots to be regarded as zero-dimensional as well as any combination of these structures.

The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or such as AlₙGaₘIn₁₋ₙ₋ₘAsₖP₁₋ₖ, where in each case 0≤n≤1, 0≤m≤1 and n+m≤1 as well as 0<k<1. For example, in this case, for at least one layer or for all layers of the semiconductor layer sequence, 0<n≤0.8, 0.4≤m<1 and n+m≤0.95 as well as 0<k≤0.5 applies. The semiconductor layer sequence may comprise dopants as well as additional components. For the sake of simplicity, however, only the essential constituents of the crystal lattice of the semiconductor layer sequence, that is, Al, As, Ga, In, N or P, are mentioned, even if these may be partially replaced and/or supplemented by small amounts of additional substances.

Preferably, the semiconductor layer sequence is based on the AlₙIn₁₋ₙ₋ₘGaₘN material system. In particular, radiation generated by the active zone during operation is in the spectral range between 350 nm and 600 nm inclusive.

According to at least one embodiment, the optoelectronic semiconductor chip comprises a first electrode and a second electrode with which the semiconductor layer sequence is electrically contacted. The electrodes may be located directly on the semiconductor layer sequence. For example, the electrodes are metallic, such that the electrodes may each comprise one or more metal layers. Thus, the semiconductor chip may be a flip chip.

According to at least one embodiment, the semiconductor layer sequence has at least one oblique facet in the region of the active zone, in particular exactly one or exactly two such facets. This at least one oblique facet is configured for beam deflection of the radiation. A beam deflection angle is, for example, at least 45° or at least 60° or at least 85° and/or at most 135° or at most 120° or at most 95°. In particular, a 90° beam deflection is performed by the oblique facet.

According to at least one embodiment, the first electrode and the second electrode are located on the same mounting side of the semiconductor layer sequence as the at least one oblique facet. In this case, the mounting side is a main side of the semiconductor layer sequence. This may mean that, when viewed from above the mounting side, both the first electrode and the second electrode are visible without line-of-sight shadowing by any material of the semiconductor layer sequence itself.

According to at least one embodiment, decoupling of the radiation takes place on an emission side of the semiconductor layer sequence opposite the mounting side. That is, the radiation can be emitted in a direction away from the electrodes.

In at least one embodiment, the optoelectronic semiconductor chip comprises a semiconductor layer sequence in which at least one active zone for generating radiation is located, and a first electrode and a second electrode with which the semiconductor layer sequence is electrically contacted. The semiconductor layer sequence has at least one oblique facet in the region of the active zone, which facet is configured for beam deflection of the radiation. The first electrode and the second electrode are located on a same mounting side of the semiconductor layer sequence as the at least one oblique facet, the mounting side being a main side of the semiconductor layer sequence. A decoupling of the radiation occurs at an emission side of the semiconductor layer sequence opposite to the mounting side. Optionally, the second electrode contacts the semiconductor layer sequence electrically in at least one cut-out and the first electrode is attached to the semiconductor layer sequence outside the at least one cut-out, the second electrode being designed as a planarization, so that the second electrode has a greater thickness than the first electrode, and the first electrode and the second electrode form a common electrical contacting plane on sides facing away from the semiconductor layer sequence, and a filling fills the at least one cut-out on the at least one oblique facet and is made of a material that is reflective for the radiation.

The semiconductor chip is in particular a surface emitting laser diode, especially based on GaInN material systems and without a thin film approach, that is, without removing a growth substrate of the semiconductor layer sequence. It may be a surface-emitting laser with a horizontal cavity, also referred to as HCSEL. ‘Surface emitting’ may mean that an emission side is oriented perpendicular to a growth direction of the semiconductor layer sequence, and ‘horizontal’ may mean in the direction parallel to the emission side.

In the semiconductor chip described here, a Bragg mirror is preferably incorporated into the epitaxially grown semiconductor layer sequence in combination with a 45° deflection prism, that is, the oblique facet. The semiconductor chip can be designed cost-effectively as a laser, since LED-like processes can be used in fabrication and no specific laser processes, such as scribing and breaking, are required.

In addition to the significantly more cost-effective realization due to wafer-level processing—without the separation process otherwise necessary for mirror coating with lasers—a number of applications can be served, for example, the pumping of wavelength conversion materials, for example, in projection applications. Other potential applications are in the automotive sector or general lighting. In addition, the surface emission allows particularly flat packages and thus high synergies with LED package technology.

According to at least one embodiment, the at least one oblique facet is located along a growth direction of the semiconductor layer sequence between the first electrode and the second electrode. This applies in particular with respect to the locations at which the respective electrode contacts the semiconductor layer sequence or injects current into the semiconductor layer sequence.

According to at least one embodiment, the at least one oblique facet is a deflection mirror within a resonator for radiation. That is, the facet in question is then not located at a resonator end and is not a resonator end mirror. For example, the facet in question acts as a deflection mirror by means of total reflection.

According to at least one embodiment, the semiconductor layer sequence comprises one or more first Bragg mirrors. The at least one first Bragg mirror is formed of semiconductor material of the semiconductor layer sequence. The first Bragg mirror may be doped or undoped. For example, a reflectivity of the at least one first Bragg mirror for the radiation is at least 20% or at least 40% and/or at most 80% or at most 60% or at most 40%. That is, the first Bragg mirror may have a comparatively low reflectivity.

According to at least one embodiment, the first Bragg mirror is located within the semiconductor layer sequence between the at least one oblique facet and the emission side. It is possible that the first Bragg mirror is the only mirror between the active zone and the emission side, viewed along the growth direction.

According to at least one embodiment, at least one second Bragg mirror is applied in places to the semiconductor layer sequence on the emission side. It is possible that the second Bragg mirror is a resonator end mirror for the radiation. For example, the second Bragg mirror or Bragg mirrors has/have a reflectivity for the radiation of at least 80% or at least 90% or at least 98%.

According to at least one embodiment, the second electrode, seen in plan view on the mounting side, runs next to the resonator and along the resonator. In particular, a region of the semiconductor layer sequence that lies in extension of the resonator can be free of the second electrode and, of course, also free of the first electrode, as seen in plan view on the mounting side.

According to at least one embodiment, the optoelectronic semiconductor chip comprise a first coating. The at least one first coating is located on the at least one oblique facet. In particular, the respective facet is completely covered by the associated first coating. In particular, the first coating is made of at least one dielectric.

According to at least one embodiment, the first coating has a low refractive index material compared to the semiconductor layer sequence. In particular, this applies to an average refractive index, averaged over the oblique facet, and to a wavelength of maximum intensity of the radiation. For example, the average refractive index of the semiconductor layer sequence at the oblique facet is greater than the refractive index of the first coating by at least 1.4, or by at least 1.0, or by at least 0.6. Thus, the first coating can be set up for total reflection of the radiation.

According to at least one embodiment, the second electrode contacts the semiconductor layer sequence electrically in at least one cut-out. In the area of the cut-out or cut-outs, the semiconductor layer sequence has a reduced thickness. Preferably, the first electrode is attached to the semiconductor layer sequence only outside the at least one cut-out.

According to at least one embodiment, the second electrode is designed as a planarization. That is, the second electrode can have a greater thickness than the first electrode. In particular, the first electrode and the second electrode form a common electrical contacting plane on sides facing away from the semiconductor layer sequence.

According to at least one embodiment, the optoelectronic semiconductor chip comprises a reflective filling. The reflective filling fills the at least one cut-out at least at the at least one oblique facet. It is possible that the cut-out is completely filled by the reflective filling together with the second electrode. The reflective filling is preferably made of or comprises at least one reflective material for the radiation, for example, aluminum, silver or gold.

According to at least one embodiment, the optoelectronic semiconductor chip further comprises a second coating. The second coating is an anti-reflective coating for the radiation. The second coating covers the emission side in places or completely. The at least one second coating is a single layer, such as a λ/4 layer, or a layer stack, such as a Bragg layer stack.

According to at least one embodiment, the optoelectronic semiconductor chip comprises outcoupling optics. The outcoupling optics is located at the emission side. The outcoupling optics is set up in particular for beam shaping of the radiation. For example, a radiation direction of the radiation and/or a divergence of the radiation can be set by means of the outcoupling optics.

According to at least one embodiment, the outcoupling optics is arranged above the at least one oblique facet as seen in plan view of the emission side. If several such facets are present, it is possible for each of these facets to be assigned its own outcoupling optics.

According to at least one embodiment, the outcoupling optics is or comprises a prism, a refractive lens, a metal lens and/or an optical grating. Combinations of several such components are also possible. Furthermore, the outcoupling optics may be combined with an optically effective coating, such as the second coating.

According to at least one embodiment, the optoelectronic semiconductor chip comprises at least one wavelength conversion element. The wavelength conversion element is preferably located on the emission side, although placement on the oblique facet, on one of the oblique facets or on all oblique facets is also conceivable. The at least one wavelength conversion element is thus arranged above and/or on the at least one oblique facet as seen in plan view of the emission side.

Further, the at least one wavelength conversion element is configured to change a wavelength of the radiation. For example, the wavelength conversion element is a light-emitting substance. If there are multiple active zones and/or multiple radiation exit regions for the radiation, different wavelength conversion elements can also be combined, for example, to generate red, green, and blue light.

According to at least one embodiment, the semiconductor layer sequence is structured into one or more emission units. For example, the or each of the emission units comprises a resonator. Along a resonator longitudinal direction, adjacent emission units may be separated from each other by the facets. In a direction transverse to the longitudinal direction of the resonator, there may be multiple resonators or only a single resonator per emission unit. The emission units can be electrically connected in parallel or can be electrically controlled individually or in groups independently of each other.

According to at least one embodiment, there are exactly two of the oblique facets per emission unit for deflecting the radiation. This means that the radiation is then guided in the resonator preferably in a [symbol] -shape.

According to at least one embodiment, there is exactly one oblique facet per emission unit for deflecting the radiation and exactly one facet oriented perpendicular to the at least one active zone for reflecting the radiation in a direction-preserving manner. This means that the radiation is then guided in the resonator preferably in an L-shape.

In the following, an optoelectronic semiconductor chip described here is explained in more detail with reference to the drawing using exemplary embodiments. Identical reference signs indicate identical elements in the individual figures. However, no references are shown to scale, rather individual elements may be shown exaggeratedly large for better understanding.

### BRIEF DESCRIPTION OF THE DRAWING

In the figures:

FIG. 1 shows a schematic cross-sectional view perpendicular to a longitudinal direction of a resonator of an exemplary embodiment of an optoelectronic semiconductor chip described herein,

FIG. 2 shows a schematic cross-sectional view parallel to the longitudinal direction of the resonator of the embodiment of FIG. 1,

FIGS. 3 and 4 show schematic top views of exemplary embodiments of optoelectronic semiconductor chips described herein,

FIGS. 5 to 11 show schematic cross-sectional views of exemplary embodiments of optoelectronic semiconductor chips described herein,

FIGS. 12 and 13 show schematic cross-sectional views of facets for exemplary embodiments of optoelectronic semiconductor chips described herein,

FIG. 14 shows a schematic cross-sectional view perpendicular to a longitudinal direction of a resonator of another example of an optoelectronic semiconductor chip, and

FIGS. 15 to 17 show schematic cross-sectional views of exemplary embodiments of optoelectronic semiconductor chips described herein.

### DETAILED DESCRIPTION

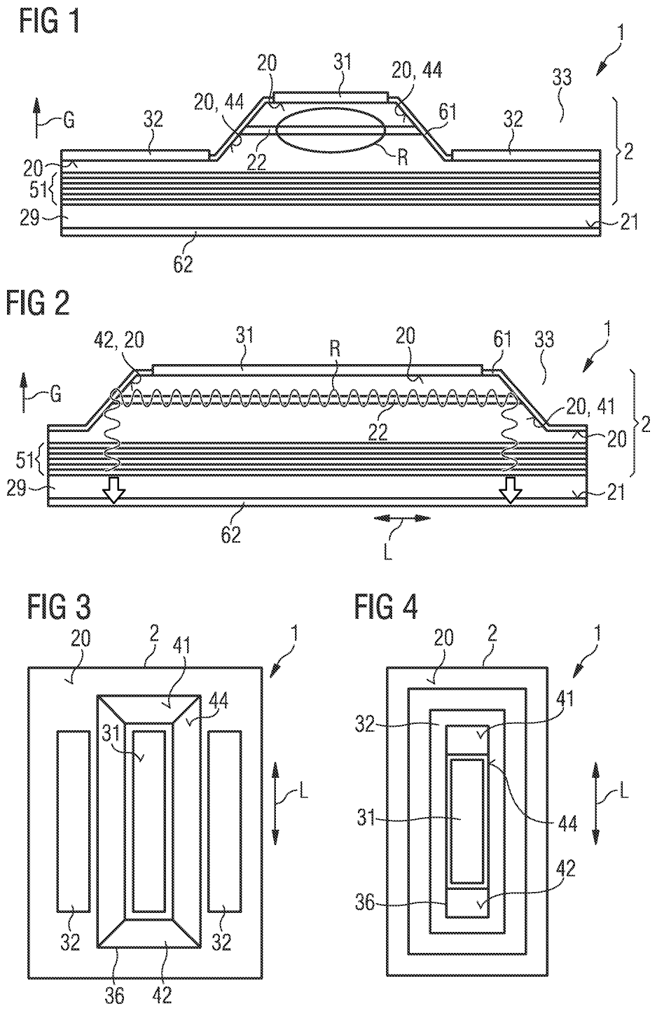

FIGS. 1 and 2 show an exemplary embodiment of an optoelectronic semiconductor chip 1. The semiconductor chip 1 is preferably a laser diode chip. The semiconductor chip 1 comprises a semiconductor layer sequence 2, which is preferably made of AlInGaN. For example, in operation, the semiconductor chip 1 is configured to generate blue light, green light and/or near-ultraviolet radiation R.

At least one active zone 22 for generating radiation R by means of electroluminescence is located in the semiconductor layer sequence 2. The active zone 22 is embedded in a waveguide, for example, and is surrounded by cladding layers on both sides along a growth direction G of the semiconductor layer sequence 2.

At the level of the active zone 22, the semiconductor layer sequence 2 is delimited by facets 41, 42, 44, these facets 41, 42, 44 being oriented obliquely to the active zone 22 and obliquely to the growth direction G. In particular, at least the facets 41, 42 are oriented at a 45° angle to both the active zone 22 and the growth direction G.

The first facet 41 and the second facet 42 are set up as deflecting mirrors for the radiation R. Further facets 44, which are aligned parallel to a resonator longitudinal direction L of a resonator in the semiconductor layer sequence 2, do not come into contact with the radiation R as intended. That is, the further facets 44 are not arranged for beam deflection or beam guidance. Regardless, the further facets 44 may be shaped in the same way as the first and second facets 41, 42, or the further facets 44 may have different angles to the growth direction G than the first and second facets 41, 42.

The facets 41, 42 are configured for total reflection of the radiation R. It is possible that on the facets 41, 42, 44 there is a first coating 61 made of a material with low refractive index relative to the semiconductor layer sequence 2. For example, the optional first coating 61 is made of SiO₂. The first coating 61 may be configured as a passivation and protective layer for the semiconductor layer sequence 2. For example, the first coating 61 has a thickness between 0.3 μm and 2 μm inclusive.

Furthermore, the semiconductor layer sequence 2 comprises a first Bragg mirror 51. The first Bragg mirror 51 may extend over the entire semiconductor layer sequence 2 and is oriented parallel to the active zone 22 and therefore perpendicular to the growth direction G. The first Bragg mirror 51 comprises a plurality of layers of preferably two different semiconductor materials having different refractive indices, which are alternately arranged. For example, the first Bragg mirror 51 comprises at least six and/or at most 50 such layers.

Optionally, the semiconductor layer sequence 2 is still located on a substrate 29, which is in particular a growth substrate for the semiconductor layer sequence 2. For example, the substrate 29 is made of sapphire or of GaN or of SiC. It is possible that the substrate 29 is thinned and has a thickness of, for example, at least 20 μm and/or of at most 0.3 mm. In contrast, the semiconductor layer sequence 2 may be thinner, for example, having a thickness of at least 4 μm and/or of at most 20 μm.

For electrical contacting, the semiconductor chip 1 comprises a first electrode 31 and a second electrode 32. The first electrode 31 is located at an area of the semiconductor layer sequence 2 where the active zone 22 is still present. In contrast, the second electrode 32 is arranged in the area of a cut-out 33. In the region of the cut-out 33, the semiconductor layer sequence 2 is thinner than in other regions. The active zone 22 is no longer present in the area of the cut-out. The electrodes 31, 32 are located on a mounting side 20 of the semiconductor layer sequence 2.

Thus, the second electrode 32 is closer to an emission side 21 of the semiconductor layer sequence 2, the emission side 21 being opposite to the mounting side 20. Both the mounting side 20 and the emission side 21 are preferably main sides of the semiconductor layer sequence 2. The emission side 21 may be planar in shape, whereas the mounting side 20 is not planar due to the cut-out 33.

Thus, a supply with current to the active zone 22 does not necessarily take place via the first Bragg mirror 51, so that the first Bragg mirror 51 can be undoped and can be optimized with respect to the reflection behavior without regard to electrical properties. Thus, for a lateral current distribution in the semiconductor layer sequence 2, the cladding layer closer to the emission side 21 can be used.

FIGS. 3 and 4 show top views of the mounting side 20, in particular for a semiconductor chip 1, as explained in connection with FIGS. 1 and 2.

According to FIG. 3, the first electrode 31 extends almost completely onto a raised strip 36 of the semiconductor layer sequence 2, this strip 36 being surrounded all around by the cut-out 33. The active zone 22 is located in this strip 36, and the active zone 22 is removed outside this strip 36. Along the resonator longitudinal direction L, the strip 36 is delimited by the first and second facets 41, 42, and in the direction transverse to the resonator longitudinal direction L by the further facets 44.

In the embodiment example of FIG. 3, the second electrode 32 has two sub-regions. These sub-regions each extend along the resonator longitudinal direction L along the strip 36. Thereby, these sub-regions can be flush or approximately flush with the first electrode 31 along the resonator longitudinal direction L on the strip 36. In extension of the strip 36 along the resonator longitudinal direction L, the mounting side 20 is optionally free of the second electrode 32.

In contrast to the illustration in FIG. 3, it is also possible for the second electrode 32 to have only one sub-region and thus to be attached to only one longitudinal side of the strip 36, along only one of the further facets 44.

In the exemplary embodiment of FIG. 4, only the first and second facets 41, 42 are oriented approximately 45° to the growth direction and to the active zone, and the further facets 44 are oriented parallel to the growth direction. Such a design of the further facets 44 is also possible in all other exemplary embodiments.

In addition, it is shown in FIG. 4 that the second electrode 32 can extend around the raised strip 36 in a frame-like manner. Along the further facets 44, a distance between the second electrode 32 and the strip 36 may be less than at the first and second facets 41, 42. Such a design of the second electrode 32 is also possible in all other exemplary embodiments.

In all other respects, the comments on FIGS. 1 and 2 apply in the same way to FIGS. 3 and 4, and vice versa.

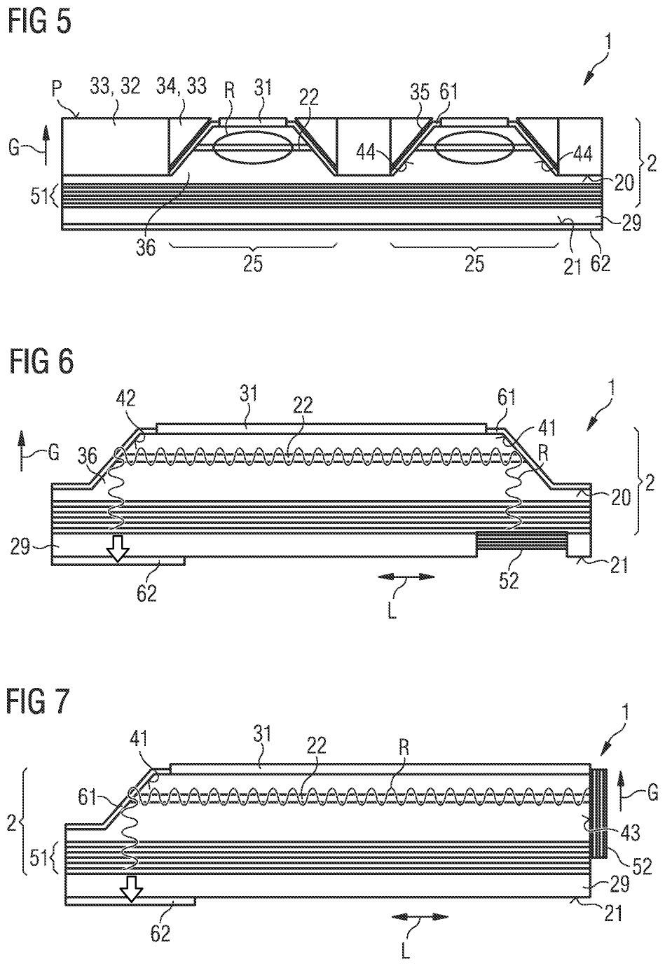

FIG. 5 shows that the semiconductor layer sequence 2 is structured into several emission regions 25. It is possible that each emission region 25 comprises exactly one strip 36 and/or exactly one resonator. Thus, the semiconductor chip 1 comprises several of the strips 36, which may be surrounded by a single common contiguous cut-out 33.

The individual emission regions 25 can be controlled electrically independently of one another, either individually or in groups, or are electrically connected in parallel. It is possible for all emission regions 25 to be of identical design within manufacturing tolerances. Alternatively, differently designed emission regions 25 may be present in combination with each other, for example, to generate radiation R of different wavelengths or colors.

Furthermore, it is illustrated in FIG. 5 that the second electrode 32 is thicker than the first electrode 31. Thus, the second electrode 32 can form a planarization to compensate for a difference in thickness caused by the cut-out 33. A common electrical contacting plane P can thus be formed by the first and second electrodes 31, 32 in order to be able to attach the semiconductor chip 1 efficiently, for example, by means of surface mounting, SMT for short, to a circuit board which is not drawn. Such planarization is also possible in all other exemplary embodiments.

Optionally, the cut-out 33 adjacent to the second electrode 32 towards the facets 41, 42, 44 is partially or completely filled with a reflective filling 34. The filling 34 is, for example, made of a metal, such as Ag or Al or Au. The filling 34 may cover the first coating 61 of low refractive index material and may be in direct contact with the first coating 61 or, as shown in FIG. 5, there may be a narrow air gap 35 between the first coating 61 and the filling 34.

In all other respects, the comments on FIGS. 1 to 4 apply in the same way to FIG. 5, and vice versa.

In the examples of FIGS. 1 to 5, the anti-reflective coating, that is, the second coating 62, is applied to the entire surface of the emission side 21 in each case, so that the emission side 21 is set up to emit radiation R both over the first facet 41 and over the second facet 42. In contrast, in FIG. 6 the second coating 62 is present only locally on the emission side 21, so that the radiation R is emitted only in the region of the emission side 21 above the second facet 42.

Further illustrated in FIG. 6 is that a second Bragg mirror 52 may be provided. The second Bragg mirror 52 is preferably highly reflective to the radiation R and forms a resonator end mirror. The second Bragg mirror 52 may be located in a hole in the substrate 29 and thus directly adjacent to the first Bragg mirror 51. Alternatively, the second Bragg mirror 52 may be deposited on the substrate 29, like the second coating 62.

In the example of FIG. 6, the first Bragg mirror 51 has a comparatively low reflectivity for the radiation R, for example, between 20% and 60% inclusive. Optionally, the first Bragg mirror 51 may also be omitted altogether, in particular if the second coating 62 has a comparatively high reflectivity for the radiation R of, for example, at least 5% and/or at most 40%. In contrast, the first Bragg mirrors 51 of FIGS. 1 to 5 may be relatively highly reflective, in particular having a reflectivity for the radiation R of between 60% and 90%, inclusive.

In all other respects, the comments on FIGS. 1 to 5 apply in the same way to FIG. 6, and vice versa.

In FIG. 7, it is shown that there is only one oblique facet 41 for deflecting the radiation R. An opposite, third facet 43 is oriented perpendicular to the active zone 22. The third facet 43 is produced, for example, by means of scribing and breaking or by means of etching. The highly reflective second Bragg mirror 52 may be located at the third facet 43.

In all other respects, the comments on FIGS. 1 to 6 apply in the same way to FIG. 7, and vice versa. In particular, this concept with a facet 43 perpendicular to the active zone 22 can be transferred to semiconductor chips 1 with multiple emission regions 25.

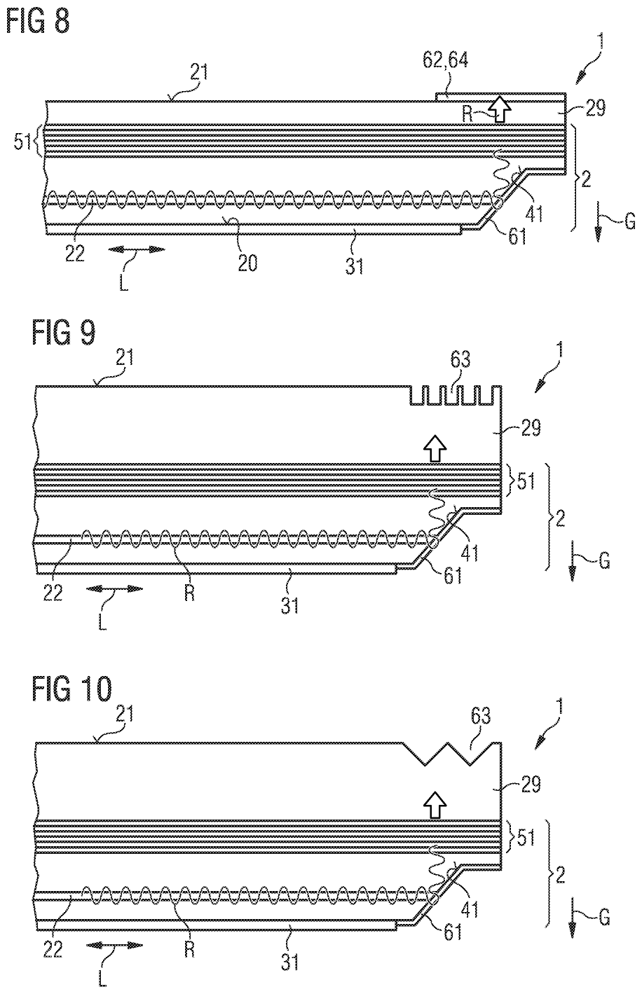

In FIG. 8, as a further option, it is shown that a wavelength conversion element 64 can be located at the emission side 21. The wavelength conversion element 64 can be used to convert a wavelength of the radiation R. For example, the wavelength conversion element 64 comprises a light-emitting substance such as a rare-earth-doped garnet such as YAG:Ce, a rare-earth-doped orthosilicate such as (Ba,Sr)₂SiO₄:Eu, or a rare-earth-doped silicon oxynitride or silicon nitride such as (Ba,Sr)₂Si₅N₈:Eu. In addition, so-called quantum dots can also be used as conversion material.

Preferably, the wavelength conversion element 64 is applied to the emission side 21 only in the area through which the radiation R passes. The wavelength conversion element 64 can be applied as a uniformly thick layer or also structured. It is possible to combine the wavelength conversion element 64 with another optically active structure, such as the second coating 62.

Due to the beam expansion by the optionally relatively thick substrate 29, it may no longer be necessary to hermetically encapsulate the semiconductor chip, especially if two emission points are possible for certain applications, such as pure projection applications with conversion, since the power density at the emission side 21 is then significantly lower here. The same applies to all other exemplary embodiments.

In all other respects, the comments on FIGS. 1 to 7 apply in the same way to FIG. 8, and vice versa.

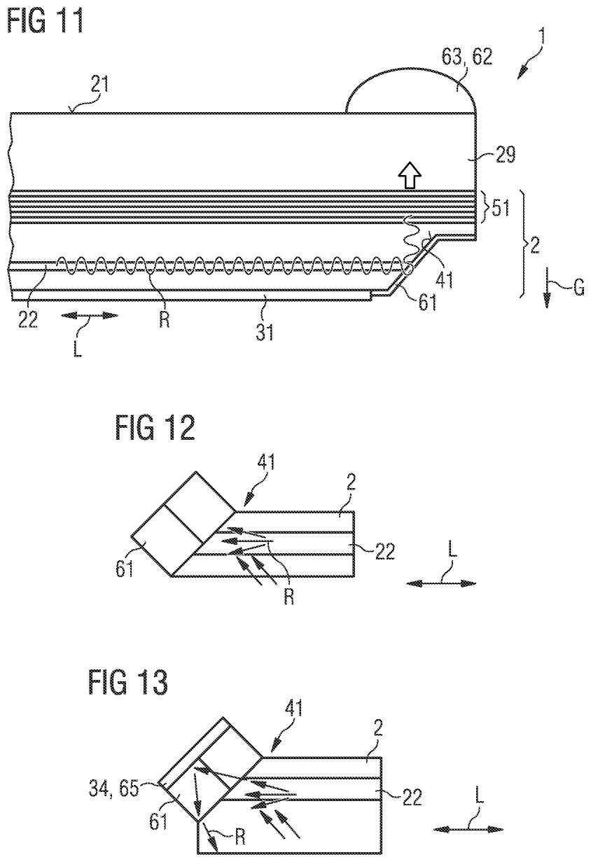

FIGS. 9 and 10 illustrate that an outcoupling optics 63 may be present. For example, the outcoupling optics 63 is an optical grating, see FIG. 9, or a prism or lens, see FIG. 10. It is possible to produce the outcoupling optics 63 directly in the substrate 29 by etching. According to FIG. 11, the outcoupling optics 63 is not fabricated in the substrate 29, but is applied to the emission side 21.

The outcoupling optics 63 can be a diffractive optics or also a meta optics. Several different outcoupling optics 63 as well as at least one wavelength conversion element 64 can also be combined with each other.

In all other respects, the comments on FIGS. 1 to 8 apply in the same way to FIGS. 9 to 11, and vice versa.

FIGS. 12 and 13 illustrate various examples of first and second facets 41, 42. According to FIG. 12, the relatively thick low refractive index first coating 61 is present on the facet 41 in question. In FIG. 13, a facet mirror 65 is also present, alternatively the reflective filling 34 is present. The facet mirror 65 is preferably made of a metal such as silver or aluminum, but can also be another Bragg mirror.

In particular, for blue or green emitting semiconductor chips 1 based on the material system AlInGaN, a refractive index jump between the semiconductor layer sequence 2 and the first coating 61, which is, for example, of SiO₂, is not very high: from about 2.4 to 1.5. This means a critical angle for total internal reflection, TIR, of about 38.7°. In the AlInGaAs material system for infrared emitting semiconductor chips 1, the critical angle is less problematic because the refractive index jump can be larger, so a typical critical angle is about 26°.

A radiation portion that does not experience TIR is lost. This reduces a feedback efficiency. This means a worse performance of the semiconductor chip 1, especially a higher laser threshold and a lower slope. Due to the facet mirror 65 behind the first coating 61, the non-TIR radiation portion, or at least a part of it, can be fed back into the resonator, so that a higher efficiency is possible.

The following should be taken into account: The thickness of the first coating 61, for example SiO₂, is typically in the range of 1×penetration depth to 7×penetration depth, in particular 2.1×penetration depth to 3.9×penetration depth, like 2.7×penetration depth to 3.3×penetration depth. This is particularly advantageous if the 45° oblique of the first or second facet 41, 42 is not exactly hit, since then the radiation component, which no longer experiences TIR, increases additionally. The penetration depth is in particular λ/n, where λ is a wavelength of maximum intensity and n is the refractive index of the first coating 61 at this wavelength, in particular at a temperature of 296 K.

Thus, the first coating 62 should be sufficiently thick to ensure sufficient TIR, but not too thick, otherwise beam misalignment of the non-TIR component will no longer ensure feedback into the waveguide.

In all other respects, the comments on FIGS. 1 to 11 apply in the same way to FIGS. 12 and 13, and vice versa.

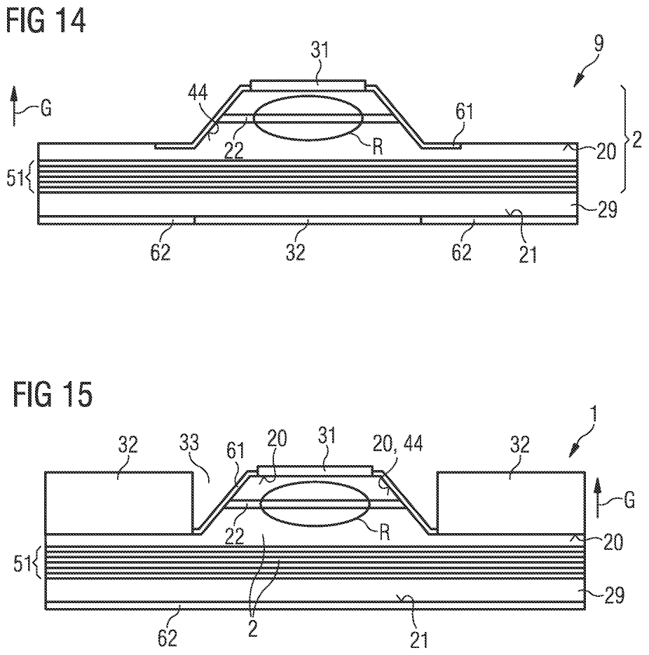

FIG. 14 shows a further example 9 of the semiconductor chip 1. In the further example 9, the second electrode 32 is not located on the mounting side 20, but on the emission side 21. Otherwise, the explanations for FIGS. 1 to 13 apply in the same way to FIG. 14.

In the exemplary embodiment of FIG. 15, the first and second electrodes 31, 32 are flush with each other along the growth direction G. In this case, the first coating 61 on the further facets 44 and the second electrode 32 can be separated by a gap. There may be a gap between the first coating 61 on the further facets 44 and the second electrode 32.

As in the preceding exemplary embodiments, the cut-out 33 extends along the growth direction G to beyond the active zone 22, so that the active zone 22 is removed in the area of the cut-out 33. As explained in connection with FIG. 4, the further facets 44 need not be arranged oblique to the growth direction G in this case, but can also run parallel to the growth direction G.

In all other respects, the comments on FIGS. 1 to 14 apply in the same way to FIG. 15, and vice versa.

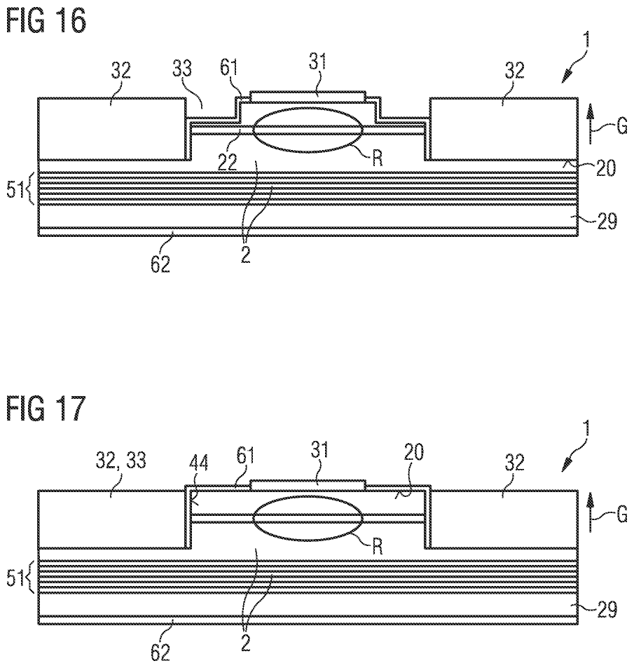

FIG. 16 illustrates that the cut-out 33 has a stepped course. This means that the active zone 22 is still present in places in the cut-out 33. Optionally, it is possible for the further facets 44 to run in each case in two sections parallel to the growth direction G. Alternatively, the further facets 44 can include sections oriented oblique to the growth direction G, analogous to FIG. 15.

Such a design of the cut-out 33 may define a strip waveguide in the semiconductor layer sequence 2 for guiding the radiation R, also referred to as a ridge waveguide. Such a ridge waveguide may also be present in all other exemplary embodiments. Thus, the semiconductor chip 1 shown in FIG. 16 is index-guided.

In all other respects, the comments on FIGS. 1 to 15 apply in the same way to FIG. 16, and vice versa.

Referring to FIG. 17, the further facets 44 are oriented perpendicular to the active zone 22. A portion of the top surface 20 where the first electrode 31 is located is formed flat. The first electrode 31 covers only a relatively small portion of this section of the top surface 20. In other words, the top surface 20 significantly overhangs the first electrode 31 laterally. When viewed in cross section perpendicular to the longitudinal direction of the resonator, a width of the first electrode 31, for example, is then at least 10% or 20% and/or at most 70% or 50% of a total width of this portion of the top surface 20. In contrast, the width of the first electrode 31 in the preceding exemplary embodiments of an index-guided semiconductor chip 1, for example, is at least 70% or 80% or 90% of the corresponding total width.

Such a design of the first electrode 31, as illustrated in FIG. 17, can thus realize a gain-controlled semiconductor chip 1. Accordingly, this is also possible in all other exemplary embodiments.

In all other respects, the comments on FIGS. 1 to 16 apply in the same way to FIG. 17, and vice versa.

The components shown in the figures preferably follow one another in the sequence indicated, in particular directly one after the other, unless otherwise described. Components not touching each other in the figures are preferably spaced apart. Insofar as lines are drawn parallel to one another, the associated surfaces are preferably likewise aligned parallel to one another. Furthermore, the relative positions of the drawn components to each other are correctly reproduced in the figures, unless otherwise specified.

The invention described herein is not limited by the description based on the embodiments. Rather, the invention encompasses any new feature as well as any combination of features, which in particular includes any combination of features in the patent claims, even if this feature or combination itself is not explicitly stated in the patent claims or embodiments.

1. An optoelectronic semiconductor chip comprising:
a semiconductor layer sequence in which an active zone configured for generating radiation is located;
a first electrode and a second electrode with which the semiconductor layer sequence is electrically contacted; and
a filling,
wherein
in a region of the active zone, the semiconductor layer sequence comprises an oblique facet which is configured for beam deflection of the radiation,
the first electrode and the second electrode being located on a same mounting side of the semiconductor layer sequence as the oblique facet and the mounting side is a main side of the semiconductor layer sequence,
decoupling of the radiation out of the semiconductor layer sequence takes place on an emission side of the semiconductor layer sequence which is opposite the mounting side,
the second electrode electrically contacts the semiconductor layer sequence in a cut-out and the first electrode is attached to the semiconductor layer sequence outside the cut-out,
the second electrode is configured as a planarization, so that the second electrode has a greater thickness than the first electrode and the first electrode and the second electrode form a common electrical contacting plane on sides facing away from the semiconductor layer sequence, and
the filling fills the cut-out at the oblique facet and is made of a material reflective for the radiation.

2. The optoelectronic semiconductor chip according to claim 1,
wherein the semiconductor layer sequence is of the material system AlInGaN, and wherein, along a growth direction of the semiconductor layer sequence, the oblique facet is located between the first electrode and the second electrode.

3. The optoelectronic semiconductor chip according to claim 1,
which is a semiconductor laser,
wherein the oblique facet is
a deflection minor within a resonator for the radiation.

4. The optoelectronic semiconductor chip according to claim 3,
wherein the semiconductor layer sequence comprises
a first Bragg minor,
wherein the first Bragg minor being located within the semiconductor layer sequence between the oblique facet and the emission side.

5. The optoelectronic semiconductor chip according to claim 3,
wherein a second Bragg mirror, which is a resonator end minor for the radiation, is applied in places to the semiconductor layer sequence on the emission side.

6. The optoelectronic semiconductor chip according to claim 3,
wherein the second electrode, as seen in plan view of the mounting side, extends adjacent to and along the resonator.

7. The optoelectronic semiconductor chip according to claim 1,
further comprising a first coating on the oblique facet, wherein the first coating comprises a low refractive index material compared to the semiconductor layer sequence and is configured for total reflection of radiation.

8. The optoelectronic semiconductor chip according to claim 1,
wherein the second electrode and the first electrode are located directly on the semiconductor layer sequence and are metallic electrodes,
wherein the second electrode is in direct contact with the filling and, viewed in a cross-section perpendicular to the emission side, is triangular in shape and terminates flush with the second electrode in the direction away from the emission side, and
wherein the filling covers the first coating in a planar manner and is in direct contact with the first coating, or an air gap is located between the first coating and the filling.

9. The optoelectronic semiconductor chip according to claim 1,
wherein the filling comprises or consists of one or more of the following materials: aluminum, silver, gold.

10. The optoelectronic semiconductor chip according to claim 1,
further comprising a second coating which is
an anti-reflective coating for the radiation,
wherein the second coating covers the emission side in places or completely.

11. The optoelectronic semiconductor chip according to claim 1,
further comprising outcoupling optics at the emission side,
wherein the outcoupling optics is arranged above the oblique facet as seen in plan view of the emission side, and
wherein the outcoupling optics comprises a prism, a refractive lens, a metal lens and/or an optical grating.

12. The optoelectronic semiconductor chip according to claim 1,
further comprising a wavelength conversion element on the emission side, wherein the wavelength conversion element is arranged above the oblique facet as seen in a plan view of the emission side, and
wherein the wavelength conversion element is configured to change a wavelength of the radiation.

13. The optoelectronic semiconductor chip according to claim 1,
comprising an emission unit which includes a resonator for the radiation,
wherein the emission unit comprises
exactly the oblique facet and one further oblique facet for deflecting the radiation.

14. The optoelectronic semiconductor chip according to claim 1,
comprising a plurality of emission units each including a resonator for the radiation,
further comprising, per emission unit, exactly one oblique facet for deflecting the radiation and exactly one facet oriented perpendicular to the at least one active zone for directionally maintaining reflection of the radiation.

15. The optoelectronic semiconductor chip according to claim 1,
wherein the semiconductor layer sequence is structured into a plurality of the emission units,
wherein the emission units being adjacent to each other as seen in plan view on the emission side.

16. An optoelectronic semiconductor chip comprising:
a semiconductor layer sequence in which an active zone configured for generating radiation is located, and
a first electrode and a second electrode with which the semiconductor layer sequence is electrically contacted,
wherein
in a region of the active zone, the semiconductor layer sequence comprises an oblique facet which is configured for beam deflection of the radiation,
the first electrode and the second electrode being located on a same mounting side of the semiconductor layer sequence as the oblique facet and the mounting side is a main side of the semiconductor layer sequence, and
decoupling of the radiation out of the semiconductor layer sequence takes place on an emission side of the semiconductor layer sequence which is opposite the mounting side.
